(19) United States
(12) Patent Application Publication
(10) Pub. No.: US 2008/0001116 A1
(43) Pub. Date: Jan. 3, 2008

(54) Method for producing bi-continuous and high internal phase nanostructures

(76) Inventors: Glenn H. Fredrickson, Santa Barbara, CA (US); Edward J. Kramer, Santa Barbara, CA (US); Bumjoon Kim, Goleta, CA (US); Craig J. Hawker, Montecito, CA (US)

Correspondence Address: BERLINER & ASSOCIATES, 555 WEST FIFTH STREET, 31ST STREET, LOS ANGELES, CA, 90013, US

(21) Appl. No.: 11/810,895

(22) Filed: Jun. 7, 2007

Related U.S. Application Data
(60) Provisional application No. 60/813,298, filed on Jun. 12, 2006.

(51) Int. Cl. H01L 29/12

(52) U.S. Cl. 252/62.3 Q; 252/182.12; 977/734

(57) ABSTRACT

A process for producing bi-continuous morphologies in polymer melts and solids, wherein two distinct domains or phases percolate and macroscopically connect throughout the composition. The process proceeds by simply mixing the components in a common solvent and casting a film by slow removal of the solvent. Bulk materials can be produced by mixing the components in an extruder, compounder, or other specialized equipment for processing molten polymers, and forming into a pellet, fiber, film, sheet, or molded part. The invention allows the production of materials with unique or unusual combinations of transparency, high electronic or ionic conductivity, high vapor transport rates, and/or high absorption rates of moisture or vapors . Particles used in the present invention are 5-10 nm to yield a scale of the bi-continuous structures of 10-50 nm. The materials can be produced in bulk form, or in films 1-100 microns thick.

### CROSS-REFERENCE TO RELATED APPLICATIONS

This application claims the benefit of U.S. Provisional Application No. 60/813,298 filed Jun. 12, 2006, and which is incorporated herein by reference.

### STATEMENT REGARDING FEDERALLY SPONSORED RESEARCH OR DEVELOPMENT

This invention was made with Government support under Grant No. DMR0520415, awarded by the NSF. The Government has certain rights in this invention.

### FIELD OF THE INVENTION

The field of the invention is bi-continuous polymer-based structures with nanometer length scales.

### BACKGROUND OF THE INVENTION

Bi-continuous polymer-based microstructures are advantageous for a number of applications. An example is membranes for separation of various gases or liquids when one of the polymer components would allow selective permeation of a molecular or atomic species in the gas or liquid while the other provides structural rigidity. Another application where bi-continuity is highly desired is in polymer-based photovoltaic films in which interpenetrating electron transporting and hole transporting conjugated polymers, if occurring on a small enough scale (10s of nanometers), would produce improved solar cell efficiencies. Bi-continuous polymer A/polymer B membranes will be also advantageous as ion transport membranes for fuel cells and/or battery applications. As coatings, bi-continuous alloys with one polymer component a pi-conjugated polymer could be useful as electrical conductors for EM shielding, or for corrosion resistance. Bi-continuous polymer systems where particles are segregated to the interfaces have other applications based on functionality of the particles. For example the particles could be catalytic, allowing reaction of gases or liquids at their surfaces. They could also facilitate electron or hole conduction, by percolative hopping from particle to particle, through the assembly. For many of these applications it is highly desirable that the scale of the microstructure be well below 100 nm.

High internal phase emulsions based on polymers have a minor polymer component that is continuous and a major component that is discontinuous. An example is a semiconducting polymer blend in which a doped pi-conjugated polymer is forced into a three dimensionally continuous minor phase by the self-assembly of colloidal polymer particles and block copolymers [1]. The continuity of the minor phase allows a minimum of costly pi-conjugated polymer to be used while still allowing carrier percolation through the structure.

Processing polymers to obtain either bi-continuous or high internal phase emulsions is very difficult, however. The interfaces between polymer phases in immiscible polymer mixtures or blends have an interfacial energy that drives coarsening of the microstructure produced either by solution casting or by melt mixing. Moreover the composition range over which bi-continuous structures can be achieved is often very narrow and depends on a careful tuning of rheological properties (such as shear viscosity) of the components. Outside of this range one typically finds discrete droplets of the low-volume fraction polymer suspended in a continuous matrix of the high volume fraction polymer. While additions of a block copolymer to the two homopolymers can lead to the formation of a thermodynamically stable bi-continuous microemulsion [2], typically the block copolymer must be much longer than the A and B homopolymers for such a microemulsion to form. Since very high molecular block copolymers are difficult and costly to synthesize, the composition range of the bi-continuous phase is again very small, and the mechanical properties of the low molecular weight homopolymers are poor, such polymeric microemulsions have never been commercialized despite their favorable bi-continuous microstructure. Recently, the formation of graft copolymer surfactants formed by reaction in an extruder offers a more practical route to all polymeric bi-continuous microemulsions [3].

Microphase separated block copolymers can themselves be bi-continuous. A bi-continuous equilibrium phase termed the double gyroid has been identified in A-b-B diblock and (A-b-B)ₙ radial block copolymers [4]. However, in contrast to other ordered block copolymer phases (e.g. lamellar, hexagonal cylinders and body centered structure of spheres), the double gyroid forms only over a very narrow range of volume fraction of A segments. Even within this range it can be difficult to obtain the gryroid phase in reasonable processing times since other (metastable) phases, such as a perforated lamellar structure, have faster formation kinetics. It has also proved difficult to obtain the double gyroid homogeneously throughout the thickness of a polymer film, a requirement for many of the uses discussed above [5]. No known commercial products are based on double gyroid block copolymer films.

There is a vast literature on alloys of two polymers with colloidal-sized particles in the range of 0.1-10 μm. Such particles can be active or passive in conferring special properties to the composition, and both patent literature [6] and academic literature [7] teach that particles in this size range can be used to create or help stabilize bi-continuous morphologies. It is important to note that the mechanisms by which particles act to promote bi-continuity in this case are complex and not well established, but most reports of co-continuous structures involve the use of particles that are fully wet by the minor component of the blend.

Aveyard et al., 2003 [12] gives a recent and comprehensive review of the state of the art for the use of small particles as surfactants for small molecule fluids (i.e. oil and water emulsions). British Patent Applications 0414829.2 and 0417437.1, referred to in Strafford et al., 2005 [8] pertain to fluid-particle stabilized gels.

Very recently computer simulation [8] and experimental [9] papers have appeared that suggest the addition of interfacially active nanoparticles to two-phase mixtures can stabilize bi-continuous emulsions of small molecule liquids [8], as well as bi-continuous microstructures of A and B homopolymers [9]. Both papers assume such fluid structures to be metastable, with an initial bi-continuous microstructure resulting from spinodal decomposition of the liquid or polymer mixture being arrested by the “jamming” of nanoparticles strongly adsorbed to the liquid/liquid or polymer/polymer interfaces. Such a mechanism requires that the mixture containing the nanoparticles be quenched from a well-mixed state, a state that is particularly difficult to achieve in molten polymer mixtures due to the strong immiscibility of most chemically different polymers of high molecular mass. The pair of A and B homopolymers used by Chung et al. [9] in fact are miscible at low temperature and immiscible at high temperatures, a relatively rare and special case.

Neither paper anticipates the possibility that a truly thermodynamically stable bi-continuous emulsion, i.e. the equivalent of a bi-continuous microemulsion, can be achieved using nanoparticle surfactants. Neither paper anticipates the possibility that addition of nanoparticles to a block copolymer or to a mixture of block copolymers and homopolymers could give rise to stable bi-continuous polymer-based microstructures with characteristic dimensions well below 100 nm. Finally, neither paper anticipates that a solution of two homopolymers and nanoparticles where the solvent is removed very slowly could result in stable bi-continuous polymer-based microstructures with characteristic dimensions well below 100 nm. Bi-continuous microstructures with such small dimensions are necessary for the most important applications discussed above.

Basically, Chung et al. [9] teach that nanoparticles with a surface treatment designed to localize the particles at interfaces are effective at kinetically arresting spinodal decomposition (a mechanism of phase separation between the two polymer components) in thin polymer films, and thereby stabilizing bi-continuous morphologies and preventing film rupture. They teach a fairly restrictive process for achieving the morphology: (a) spin down the mixture, (b) remove the solvent, (c) anneal at a temperature where the mixture is homogeneous, (d) heat through the lower critical solution temperature to start the spinodal decomposition process, and, finally, (e) rapidly cool the film to lock in the structure.

### BRIEF SUMMARY OF THE INVENTION

This invention provides a process for producing bi-continuous morphologies in polymer melts and solids, wherein two distinct domains or phases percolate and macroscopically connect throughout the composition. The process can be formed by melt mixing or preferably by simply mixing the components in a common solvent and casting a film by slow removal of the solvent. Bulk materials can be produced by mixing the components in an extruder, compounder, or other specialized equipment for processing molten polymers, and forming into a pellet, fiber, film, sheet, or molded part.

The invention allows the production of materials with unique or unusual combinations of properties (e.g. transparency and high electronic carrier collection efficiency) that would be impossible or very difficult to achieve at a comparable cost. Particles used in the present invention are preferably smaller (5-10 nm) than those used in Chung et al. (18-22nm), although the invention can be practiced with particle sizes in the range 1-50 nm. The scale of the bi-continuous structures produced by this invention is below 500 nm, preferably 10-50 nm, much smaller than in Chung et al. (900-2000 nm). Moreover, the preferred films produced in this invention are thicker (1-100 microns) than in Chung et al. (550-3000 nm), although the invention can be used to create films of thickness 500 nm-100 microns and to produce bulk compositions, rather than films.

More particularly, a method is provided for forming a solid bi-continuous composition, comprising blending one or more polymers with a surfactant material formed of one or more nanoparticle surfactants. A nanoparticle surfactant is a nanoparticle whose surface has been treated so that in the fluid state of forming the composition the particle is strongly attracted to the interfaces separating the two continuous phases. In one embodiment of the method, an AB block copolymer is blended with the surfactant material, for example by solvent or melt blending with the surfactant material under conditions to form a bi-continuous film, sheet, fiber, pellet or injection molded part structure. The bi-continuous solid composition is obtained from a bi-continuous fluid precursor in such a process by cooling the material or removing a solvent component. In another embodiment of the method, two homopolymers are solvent blended with the surfactant material under conditions to form a film in which the bi-continuous structure has a thickness between 500 nm and 100 microns. In still another embodiment of the method, the two polymers are melt blended with the surfactant material under conditions to form a bi-continuous bulk composition. Again, the bi-continuous solid composition is obtained from a bi-continuous fluid precursor by cooling the material or removing a solvent.

Novel solid bi-continuous compositions are provided in which a polymer is blended with a surfactant material formed of one or more nanoparticle surfactants. In one embodiment of the composition, the novel composition is a block copolymer blended with the surfactant material to form the structures described above. In another embodiment of the composition, the composition is a bi-continuous film comprising two homopolymers solvent blended with the surfactant material and having a thickness in the range 500 nm-100 microns. In still another embodiment of the composition, the composition is a bi-continuous bulk composition comprising two homopolymers melt blended with the surfactant material.

Many novel products formed of the foregoing compositions are provided in accordance with this invention, products in which the nanoparticles play an active role in the performance of the product and products in which the nanoparticles play a passive role. Products can be formed from polymers and nanoparticles that do not absorb or appreciably scatter light whereby the product can be transparent.

### BRIEF DESCRIPTION OF THE DRAWINGS

For a more complete understanding of the present invention, reference is now made to the following descriptions taken in conjunction with the accompanying figures, in which:

FIG. 1(a) is a transmission electron micrograph of the microstructure of a polystyrene-b-poly(2-vinylpyridine) (PS-b-P2VP) diblock copolymer with 3.5 volume % of surfactant PS-SH coated gold (Au) nanoparticles. The morphology is lamellar, with PS domains light grey, P2VP domains dark grey, and Au particles shown as black dots;

FIG. 1(b) is a transmission electron micrograph of the microstructure of a PS-b-P2VP diblock copolymer with 9 volume % of surfactant PS-SH coated gold nanoparticles. The morphology is bi-continuous;

FIG. 2(a) is a transmission electron micrograph of a PS-b-P2VP block copolymer microstructure upon inclusion of 20 volume % Au nanoparticles coated with an areal density of PS-SH chains (2.1 chains/nm²) greater than 1.5 chains/nm². A lamellar morphology is observed and the Au nanoparticles (black dots) are localized in the PS domains (light grey) of the block copolymer. The particles in this case are not “surfactant nanoparticles” because they do not localize at the PS-P2VP interfaces;

FIG. 2(b) is a lower magnification transmission electron micrograph of the same composition shown in FIG. 2(a). Large regions of macroscopically phase separated particles coexist with the lamellar phase;

FIG. 3(a) is a transmission electron micrograph of a mixture of immiscible PS and P2VP homopolymers to which 3 volume % of surfactant Au nanoparticles has been added. The P2VP phase is stained dark gray, the PS phase is light grey, and the Au particles appear as very small black dots;

FIG. 3(b) is a transmission electron micrograph of a mixture of immiscible PS and P2VP homopolymers to which 17.2 volume % of surfactant Au nanoparticles has been added. The structure is bi-continuous;

FIG. 4(a) is a transmission electron micrograph of the microstructure of a PS-b-P2VP diblock copolymer to which 14 volume % of surfactant PS-SH coated gold nanoparticles has been added; and

FIG. 4(b) is a transmission electron micrograph of the microstructure of a PS-b-P2VP diblock copolymer to which 28 volume % of surfactant PS-SH coated gold nanoparticles has been added.

### DETAILED DESCRIPTION OF THE INVENTION

The process comprises the blending, under solution or melt conditions, of one or more nanoparticle surfactants with a base polymer resin. The base polymer resin can be an AB block or graft copolymer of various architecture, including AB diblock, ABA triblock, (AB)ₙ linear multiblock, and (AB)ₙ radial block copolymers, a blend of A and B homopolymers, or a blend of A and B polymers, where either A, B, or both polymers are random or statistical copolymers. The base polymer resin has a two-phase or two-domain morphology in the melt and in the solid state such that one phase or domain is enriched in segments of polymer or block A and the second phase or domain is enriched in segments of polymer or block B.

The nanoparticle surfactant is comprised of a nanoparticle, either organic or inorganic, whose dimensions range from 1 nm to 100 nm, and whose surface has been given an appropriate treatment. Appropriate surface treatments are methods that will produce a localization of the particle at the interface between the A and B domains or phases. Such treatments include: grafting of a mixture of A and B homopolymers to the surface of the particle; grafting of a low areal density of homopolymer A when the bare nanoparticle surface strongly attracts homopolymer B; grafting of a random or statistical copolymer of A and B; grafting of a mixture of polymer A and polymer C, where polymer C has a strong attraction to segments of polymer or block B; grafting of a mixture of polymer C and polymer D, where polymer C has a strong attraction to segments of polymer or block B and polymer D has a strong attraction to segments of polymer or block A; or other chemical modification of the surface of the particles to ensure that the particles are strongly attracted to the polymer-polymer interfaces.

The invention incorporates nanoparticle surfactants with particle diameters preferably below 10 nm that strongly adsorb to interfaces between two homopolymers (A and B) or to interfaces between A and B blocks in a diblock, triblock, multiblock, graft, or radial block copolymer. Such nanoparticle surfactants can be constructed in a large number of possible ways. For example short chains of polymers A and B can be strongly attached to the bare nanoparticle surface [10]. Such attachment can be produced by a “grafting to” approach or a “grafting from” method. If the short A and B chains strongly repel each other and there is some mobility of the attachment points along the surface, they can undergo a two dimensional phase separation on the nanoparticle surface, thus forming a so-called “Janus” particle, one with an A-enriched hemispherical surface and a B-enriched hemispherical surface. Such nanoparticles will be very strongly bound to the A/B interfaces in a polymer mixture or block copolymer. A second method of creating surfactant nanoparticles takes advantage of a situation where the B polymer is preferentially attracted to the bare nanoparticle surface. In this case, short A polymer chains can be grafted to the particle at a low areal density. Strong adsorption of such partially-coated nanoparticles to A/B polymer interfaces will occur because the exposed bare particle surface can contact B polymer or block segments, while simultaneously the grafted A polymer segments can contact the A polymer or block segments of the base resin [11]. Again, if motion of A chains on the partially covered nanoparticle surface is possible by surface diffusion, even stronger adsorption to A/B interfaces will result. However any nanoparticle with an approximately “neutral” surface relative to the A and B polymers or blocks will work satisfactorily as long as the interfacial tension γ_{AB} of the A/B interface is large enough. For example a nanoparticle surface covered with chains of random copolymer of A and B will adsorb to such an interface. The adsorption energy of such a nanoparticle to the A/B interface can be described by the formula πr²γ_{AB}(1−|(γ_{AP}−γ_{BP})/γ_{AB}|)², where r is the radius of the coated nanoparticle and γ_{AB}, γ_{AP} and γ_{BP} are the polymer A-polymer B interfacial tension, polymer A-particle surface free energy, and polymer B-particle surface free energy, respectively. An adsorption energy of more than a few k_{B}T calculated by this formula, where k_{B} is Boltzmann's constant and T is absolute temperature, should be sufficient to create a practically useful surfactant nanoparticle. Nanoparticles adsorbed to an interface will decrease the interfacial tension for thermodynamic reasons first deduced by Gibbs more than a century ago and quantified by what is now called the Gibbs adsorption equation. Once the interfacial tension for a symmetric blend of A and B polymers is reduced to nearly zero, a microemulsion forms since the free energy to create more interface and thus adsorb more nanoparticles is much less than the thermal energy k_{B}T. Such microemulsions are well known in oil-water-surfactant systems, as are the block copolymer/homopolymer ones discussed above. Up until the present invention, however, bi-continuous microemulsions based on nanoparticles and polymers have not been observed. The ability of surfactant nanoparticles to induce a bi-continuous morphology in an AB diblock copolymer was particularly unexpected.

A wide range of products can be envisoned that require separate nanometer scale domains of different polymeric materials and where the properties and performance of the product depend on both phases or domains being three-dimensionally continuous (bi-continuous morphology). The process of the invention uses nanoparticles residing at the interfaces between the domains to create and stabilize the bi-continuous morphology. The nanoparticles can play an active or passive role in the performance of the material, device, or product. Examples of bi-continuous products with active particles include:
selective thin film membranes with nanoparticle catalysts embedded in the membrane;
polymeric photovoltaic cells based on small but continuous domains of p-type conjugated polymer interspersed with continuous arrays of n-type fullerene nanoparticles;
polymeric photovoltaic cells based on small but continuous domains of p-type conjugated polymer and small continuous domains of n-type conjugated polymer with nanoparticles at the interfaces that can act as a sensitizer for the enhanced absorption of solar radiation;
antireflection coatings where one of the polymers is removed and the nanoparticles provide control of the average refractive index of the coating;
containers, liners, or films where one continuous domain provides a selective path for a vapor while the nanoparticles act to absorb the vapor;
containers, liners, or films where one continuous domain provides a selective path for releasing a fragrance, flavor, or other small molecule, while the nanoparticles provide a reservoir for the molecule to be released; and
moisture absorbing compositions with dessicant nanoparticles that possess improved melt processability and mechanical properties.

Examples of products with passive particles include:
a bi-continuous alloy of two polymers with exceptional strength and toughness and extension at break, while maintaining a high modulus. Such alloy could be either a thermoplastic or a thermoset material;
a bi-continuous alloy of two polymers with exceptional transparency, along with other desirable combinations of physical properties. Such alloy could be either a thermoplastic or thermoset material; and
controlled transport films, wherein one phase provides mechanical support and good melt processability and the other allows for the transport of a small molecule gas, moisture, or another vapor.

Any of these materials can be transparent (do not scatter light) because of the small sizes of the domains and particles, provided that neither the polymers nor the nanoparticles absorb light.

The following examples will further illustrate the invention.

### EXAMPLE 1

A bi-continuous polymer microstructure consisting of gold nanoparticles coated with an areal chain density of 0.85 chains/nm² of polystyrene end-functional thiols (PS-SH) synthesized by methods disclosed in Chiu et al., 2005 [10] and a diblock copolymer of polystyrene (PS) and poly(2-vinylpyridine) (P2VP) cast slowly from the non-selective solvent dichloromethane. The PS-SH chains had a degree of polymerization N of about 24 and a polydispersity index (PDI) of 1.1, while the PS-b-P2VP diblock copolymer had a PS block with N=875 and a P2VP block with N=1000

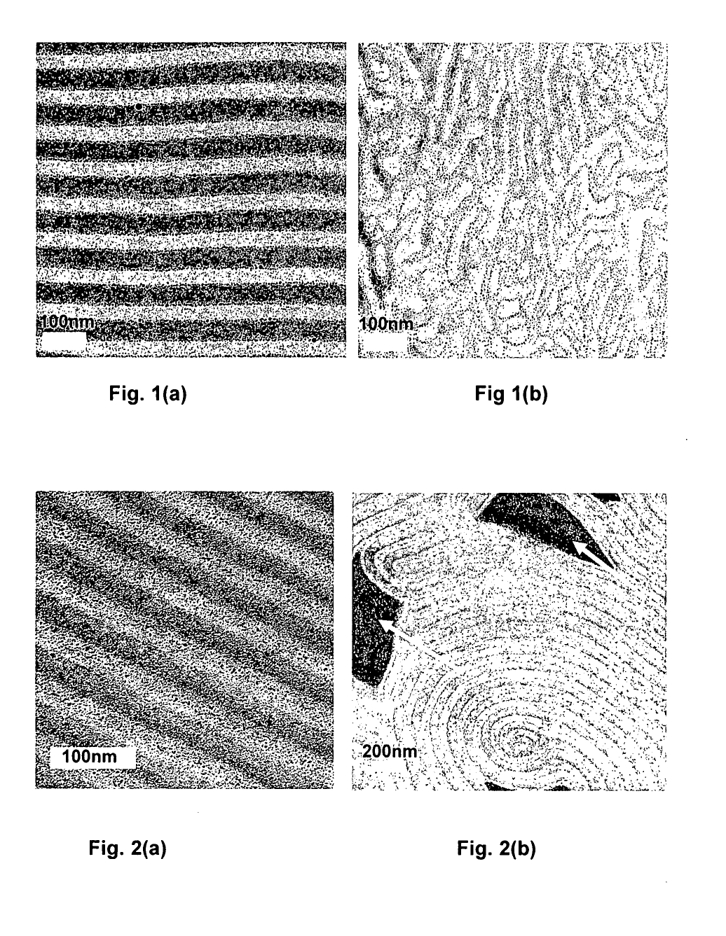

FIG. 1(a) shows the microstructure of cross-section of a film containing the PS-b-P2VP diblock copolymer and 3.5% by volume of the PS-SH coated nanoparticles. A well ordered lamellar microstructure is seen with the gold nanoparticles appearing as small black dots mainly at the interfaces between the PS and P2VP domains, the latter being stained dark grey with an iodine vapor treatment.

### EXAMPLE 2

As the volume fraction of PS-SH coated gold nanoparticles in Example 1 is increased, the microstructure of the PS-b-P2VP diblock copolymer changes dramatically. FIG. 1(b) shows that when 9% by volume of the PS-SH coated nanoparticles are added, the microstructure of the PS and P2VP domains becomes bi-continuous. The TEM micrographs shown are fully consistent with a cross-section of a bi-continuous polymer morphology. It is particularly noteworthy that the bi-continuous domains of PS and P2VP have typical dimensions of 30 to 50 nm. The sizes of these domains are much smaller than those seen in the bi-continuous polymer blend films of Strafford et al. [8] and Chung et al. [9], which indicates that they are formed by a quite different mechanism.

### EXAMPLE 3

It is important that the nanoparticles segregate strongly to the interfaces. For example, if the areal chain density of the PS-SH chains on the Au nanoparticles is increased to above 1.5 chains/nm², the particles segregate to the center of the PS domains of the PS-b-P2VP block copolymer. FIG. 2(a) shows a high magnification transmission electron micrograph of the block copolymer microstructure when such Au nanoparticles with a high areal density of PS-SH chains on their surfaces are added at 20% volume fraction to the PS-b-P2VP block copolymer. The figure shows that the particles (small black dots) are primarily localized in the PS domains (light grey). Because these particles do not strongly segregate to the PS-P2VP interfaces, they are not surfactant nanoparticles as disclosed in the present invention.

### EXAMPLE 4

FIG. 2(b) shows a lower magnification micrograph of the same composition in Example 3. Because of the high areal density of PS-SH chains on the Au particle surfaces, the particles not only localize in the PS domains, but also phase separate into large nanoparticle aggregates (shown by the arrows) surrounded by the block copolymer domains. The block copolymer remains lamellar and no bi-continuous structure is formed as the volume fraction of these nanoparticles is further increased. Instead, the relative volume occupied by the particle aggregate phase grows with increasing nanoparticle volume fraction. Such samples are described as macrophase separated, the nanoparticles clustering to form their own phase separate from the block copolymer. No bi-continuous microstructure is formed.

### EXAMPLE 5

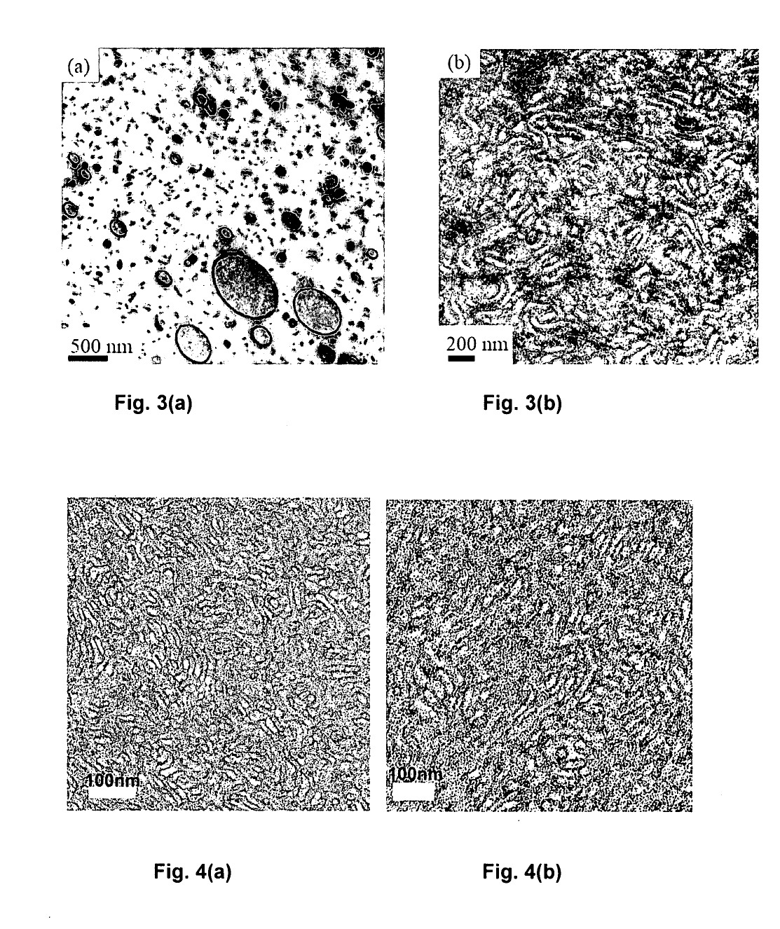

The surfactant nanoparticles, when mixed with A and B homopolymers, also can produce two phase morphologies that are bi-continuous with very small phase sizes. An example of this effect can be seen by mixing the PS-SH coated Au surfactant nanoparticles disclosed above (0.85 chains/nm² of PS-SH chains on the Au nanoparticles), polystyrene homopolymer (N=1990, PDI 1.05), and poly(2-vinylpyridine) homopolymer (N=1450, PDI=1.1). Equal volumes of the PS and P2VP homopolymers are mixed in a dichloromethane solution to which is added various volume percentages of the surfactant Au nanoparticles. With no added nanoparticles, a slowly dried solution cast film of the two homopolymers consisted of a layer of P2VP against a silicon substrate and a layer of PS covering the surface. The two homopolymers are phase separated on a large (macroscopic) length scale. When a small volume percentage (3%) of the nanoparticle surfactant is added to the mixture of homopolymers, a slowly dried solution cast film of the two homopolymers shows droplets of P2VP in a continuous PS matrix as shown in FIG. 3(a). The surfaces of the P2VP droplets are covered with the surfactant Au nanoparticles but the microstructure formed is not bi-continuous; the P2VP phase is discontinuous.

### EXAMPLE 6

When the procedure of Example 5 is followed but the volume percentage of the surfactant nanoparticles is increased to 17.2%, the microstructure of the mixture is completely changed as seen in FIG. 3(b). The composition exhibits a bi-continuous microstructure in which the sizes of the PS and P2VP phases are well below 100 nm.

### EXAMPLES 7 AND 8

The bi-continuous microstructures obtained with surfactant nanoparticles are found over a wide range of experimental conditions in contrast to block copolymer/homopolymer microemulsions. As an example we show in FIG. 4 that the microstructure of the PS-b-P2VP diblock copolymer mixture with the surfactant PS-SH nanoparticles, described in Example 2 and shown in FIG. 1(b) corresponding to 9 volume % of nanoparticles, remains bi-continuous as the volume % of nanoparticles is increased to 14% (Example 7 and FIG. 4(a)) and to 28% (Example 8 and FIG. 4(b)). The P2VP domains are stained dark grey with an iodine vapor treatment.

The teaching provided by these examples would enable one skilled in the art to prepare bi-continuous polymer microstructures from a broad range of polymer components A and B, or AB block or graft copolymers, using a broad range of surfactant nanoparticles P.

Examples of polymers that can be used as polymer components A and B, or as blocks in AB block or graft copolymers include: polystyrenes; polyvinyl pyridines; polyethylenes polypropylenes; poly(ethylene-r-alpha olefin) copolymers; cyclic olefin copolymers; fully and partially hydrogenated polystyrenes, polyisoprenes, polybutadienes, and their copolymers; ethylene-propylene and ethylene-propylene-diene rubbers; polybutadienes; polyisoprenes; polyvinyl chlorides; polyethylene oxides and polyethylene glycols; polyphenylene oxides and ethers; polycarbonates; polyamides; polyesters; polylactides; polyurethanes; epoxies; polyvinyl alcohols; polyvinyl acetates; polyacrylic acids and acrylic acid copolymers; polymethacrylates and copolymers; polyacrylates and copolymers; EVA and EVOH copolymers; SAN and SMA copolymers' ABS copolymers; nitrile rubbers; chlorinated polyethylenes; fluoropolymers; polyfluorenes; polyanilines; polythiophenes; polyphenylenes; polyacetylenes; polypyroles; polyvinylcarbazoles; among others.

Beyond gold nanoparticles, we anticipate that a wide class of nanoparticle surfactants formed by appropriate surface treatment of nanoparticulate metals, metal oxides, semiconductors, nitrides, silicates, aluminosilicates, clays, carbonaceous materials, and organic polymers could be used in this invention.

High internal phase emulsions with nanoparticles in the continuous phase can also be produced using this invention. For example block copolymers with nanoparticle surfactants can be mixed in a common solvent with colloidal particles, the latter comprising 60% or greater by volume of the composition. If one domain of the block copolymer wets the colloidal particles, upon slow removal of the solvent a bi-continuous microstructure of the block copolymer and nanoparticles will form a continuous film phase surrounding the larger colloidal particles (discrete phase) even at low nanoparticle and block copolymer volume fractions. The resulting high internal phase emulsion composition will allow transport through the bi-continuous microstructure formed by the block copolymer and surfactant nanoparticles. Such high internal phase polymer emulsions constitute highly functional materials where the major part of the material can be made up of an inexpensive polymer or inorganic colloid.

While the examples shown here were formed from solution, as would be appropriate for many of the film applications discussed above, the fact that a non-selective solvent was used and the solvent was removed very slowly means that the structures formed are close to thermodynamic equilibrium. Using suitable nanoparticle surfactants, it should be clear to one skilled in the art that the present invention can also be practiced for polymers and nanoparticles mixed in the molten state.

### REFERENCES

1. R. Mezzenga, J. Ruokolainen, G. H. Fredrickson, E. J. Kramer, D. Moses, A. J. Heeger and O. Ikkala, Science, 299 1872-1874 (2003)
2. F. S. Bates, W. W. Maurer, P. M. Lipic, M. A. Hillmyer, K. Almdal, K. Mortensen, G. H. Fredrickson, and T. P. Lodge Phys. Rev. Lett. 79 849-852 (1997)
3. H. Pernot, M. Baumert, F. Court and L. Leibler, Nature Materials, 1 54-58 (2003).
4. D. A. Hajduk, P. E. Harpre, S. M. Gruner, C. C. Honeker, G. Kim, E. L. Thomas, and L. J. Fetters, Macromolecules, 27 4063 (1994).
5. R. C. Hayward, P. C. A. Alberius, E. J. Kramer and B. F. Chmelka, Langmuir, 20, 5998-6004 (2004).
6. U.S. Pat. Nos. 6,486,231 and 7,005,459.
7. T. W. Cheng, H. Keskkula, and D. R. Paul, Polymer 33, 1606-1619 (1992).
8. K. Strafford, R. Adhikari, J.-C. Desplat and M. E. Cates, Science 309 2198-2201 (2005)
9. H. Chung, K. Ohno, T. Fukuda and R. J. Composto, Nanoletters, 5 1878-1882 (2005).
10. J. J. Chiu, B. J. Kim, E. J. Kramer, D. J. Pine, J. Amer. Chem. Soc. 127 5036-5037 (2005).
11. B. J. Kim, J. Bang, C. J. Hawker and E. J. Kramer, “Effect of Areal Chain Density on the Location of Polymer Modified Gold Nanoparticles in a Block Copolymer Template”, Macromolecules 2006, in press.
12. Aveyard, R.; Binks, B. P.; Clint, J. H. Adv. Colloid Interface Sci. 2003, 100-102, 503-546.

The claims:

1. A method for forming a solid bi-continuous composition, comprising blending a base polymer material formed of one or more polymers with a surfactant material formed of one or more nanoparticle surfactants, in the presence or absence of a solvent, by:
(a) blending a block copolymer with the surfactant material, in the presence of a solvent and then removing a solvent, or cooling the composition;
(b) solvent blending two immiscible or partially miscible polymers with the surfactant material and then removing the solvent under conditions to form a film in which the bi-continuous structure has domain sizes below 500 nm; or
(c) melt blending two immiscible or partially miscible polymers with the surfactant material and then cooling under conditions to form a bi-continuous bulk composition

2. The method of claim 1 in which the polymer is a block copolymer and is solvent or melt blended with the surfactant material under conditions to form a bi-continuous film, sheet, fiber, pellet or molded or formed part structure.

3. The method of claim 1 in which the two immiscibile or partially miscible polymers are homopolymers, random copolymers, or statistical copolymers and are solvent blended with the surfactant material under conditions to form a film with a bi-continuous morphology having domain sizes below 500 nm.

4. The method of claim 1 in which the two immiscibile or partially miscible polymers are homopolymers, random copolymers, or statistical copolymers and are melt blended with the surfactant material under conditions to form a bi-continuous bulk composition.

5. A solid bi-continuous composition comprising a base polymer material formed of one or more polymers blended with a surfactant material formed of one or more nanoparticle surfactants in which the base polymer material is:
(a) a block copolymer blended with the surfactant material
(b) two immiscible or partially miscible polymers selected from homopolymers, random copolymers, or statistical copolymers that are solvent blended with the surfactant material and formed into a film with phase or domain sizes below 500 nm; or
(c) two immiscible or partially miscible polymers selected from homopolymers, random copolymers, or statistical copolymers that are melt blended with the surfactant material.

6. The composition of claim 5 in which the solid bi-continuous composition is a film, sheet, fiber, pellet or molded or formed part comprised of block copolymer that is solvent or melt blended with the surfactant material.

7. The composition of claim 5 in which the solid bi-continuous composition is comprised of two immiscible or partially miscible polymers selected from homopolymers, random copolymers, or statistical copolymers that are solvent blended with the surfactant material to form a bi-continuous structure with domain or phase sizes below 500 nm.

8. The composition of claim 5 in which the solid bi-continuous composition is a bulk composition comprised of two immiscible or partially miscible polymers selected from homopolymers, random copolymers, or statistical copolymers that are melt blended with the surfactant material.

9. A product formed of a solid bi-continuous material comprising a base polymer material formed of one or more polymers blended with a surfactant material formed of one or more nanoparticle surfactants in which the base polymer is:
(a) a block copolymer blended with the surfactant material;
(b) two immiscible or partially miscible polymers selected from homopolymers, random copolymers, or statistical copolymers that are solvent blended with the surfactant material and formed into a film with phase or domain sizes below 500 nm; or
(c) two immiscible or partially miscible polymers selected from homopolymers, random copolymers, or statistical copolymers that are melt blended with the surfactant material.

10. The product of claim 9 in which the nanoparticles play an active role in the performance of the product.

11. The product of claim 10 in which the product is a selective thin film membrane with nanoparticle catalysts embedded in the membrane.

12. The product of claim 10 in which the product is a polymeric photovoltaic cell based on small but continuous domains of p-type conjugated polymer interspersed with continuous arrays of n-type fullerene nanoparticles.

13. The product of claim 10 in which the product is a polymeric photovoltaic cells based on small but continuous domains of p-type conjugated polymer and small continuous domains of n-type conjugated polymer with nanoparticles at the interfaces that act as a sensitizer for the enhanced absorption of solar radiation.

14. The product of claim 10 in which the product is an antireflection coating where one polymer phase or domain is removed and the nanoparticles provide control of the average refractive index of the coating.

15. The product of claim 10 in which the product is a container, film, molded part, or liner where one polymer phase or domain provides a selective path for a vapor or small molecule while nanoparticles act to absorb vapor or small molecule.

16. The product of claim 10 in which the product is a container, film, molded part, or liner where one polymer phase or domain has been removed to provide a selective path for a vapor or small molecule while nanoparticles act to absorb vapor or small molecule.

17. The product of claim 10 in which the product is a container, film, molded part, or liner where one continuous phase or domain provides a selective path for releasing a fragrance, flavor, or other small molecule, while the nanoparticles provide a reservoir for the molecule to be released.

18. The product of claim 10 in which the product is a moisture absorbing composition with dessicant nanoparticles that possesses improved melt processability and mechanical properties.

19. The product of claim 9 in which the nanoparticles play a passive role in the performance of the product.

20. The product of claim 19 in which the product is a controlled transport film, wherein one phase provides mechanical support and the other allows for the transport of a small molecule gas, moisture, or another vapor

21. The product of claim 19 comprising a bi-continuous alloy of two polymers in which the bi-continuous morphology confers exceptional strength, toughness, and/or extension at break, while maintaining a high modulus.

22. The product of claim 19 comprising a bi-continuous alloy of two polymers in which the bi-continuous morphology confers optical transparency along with other desirable properties.

23. The product of claim 19 comprising a bi-continuous alloy of two polymers in which the bi-continuous morphology confers electrical or ionic conductivity along with other desirable properties.

24. The product of claim 9 constituted as a thermoplastic material.

25. The product of claim 9 constituted as a thermoset material.

26. The product of claim 9 in which neither the polymer material nor the surfactant material absorb light whereby the product is transparent.
